(19) United States
(12) Patent Application Publication
(10) Pub. No.: US 2020/0319232 A1
(43) Pub. Date: Oct. 8, 2020

(54) DEVICE FOR MEASURING THE INTENSITY OF A CURRENT

(71) Applicants: CONTINENTAL AUTOMOTIVE FRANCE, Toulouse (FR); CONTINENTAL AUTOMOTIVE GmbH, Hannover (FR)

(72) Inventors: Christopher PERON, PINS-JUSTARET (FR); Angelo PASQUALETTO, TOULOUSE (FR); Sébastien SANCHEZ, COLOMIERS (FR)

(21) Appl. No.: 16/955,501

(22) PCT Filed: Dec. 11, 2018
(86) PCT No.: PCT/FR2018/053188

§ 371 Date: Jun. 18, 2020

(30) Foreign Application Priority Data
Dec. 19, 2017 (FR) 1762459

(51) Int. Cl. G01R 1/20; H05K 1/02; H05K 1/16

(52) U.S. Cl. CPC G01R 1/203; H05K 1/165; H05K 1/0265

(57) ABSTRACT

Disclosed is a device for measuring the intensity of a current, suitable for measuring the intensity of a current flowing through a supply capacitor of an electronic control unit of a motor vehicle. The device includes at least one printed circuit, the printed circuit including at least one conductive layer and at least one first set of tracks printed on the at least one conductive layer, the first set of tracks including at least one first part having a first inductance and at least one second part having a second inductance, the first part and the second part being arranged so that the total inductance of the device is lower than each of the first inductance and the second inductance.

### BACKGROUND OF THE INVENTION

### Field of the Invention

The invention relates to the field of measuring the intensity of a current and relates more particularly to a device for measuring the intensity of a current flowing through a supply capacitor of an electronic control unit of a motor vehicle.

The invention aims in particular to improve the measurement of the intensity of a control current for a fuel injector.

### Description of the Related Art

In a combustion-engine motor vehicle, the injection of fuel into the cylinders is carried out by injectors controlled by a drive module integrated in an electronic control unit, also called an ECU.

In a known manner, an electronic control unit comprises a microcontroller, a direct-current-to-direct-current (DC-DC) converter, a supply capacitor and a drive module for the injectors. The converter is a step-up voltage converter that generates a control current allowing the drive module to control the opening of the fuel injectors. Thus, during the operation of the electronic control unit, the microcontroller controls the drive module so that it controls the injectors from the control current supplied by the converter.

The various components need to be sized in order to guarantee a minimum service life of the electronic control unit. In particular, it is necessary to choose the supply capacitor on the basis of the rms current flowing through it, which is generated by both the converter and the drive module. To size the supply capacitor, it is necessary to measure the value of the intensity of this rms current during the development of the electronic control unit.

To carry out such an intensity measurement, a first known solution involves connecting a current probe in series with the supply capacitor. In practice, it is necessary to use an additional wire in order to insert the current probe into the electrical circuit to which the supply capacitor is connected. However, the use of such a current probe has drawbacks. Certainly, when the current flows through both the additional wire and the current probe, the measurement is disturbed by a parasitic inductance generated by these additional elements. In other words, the current intensity value measured by the current probe will not be strictly equal to that of the current flowing through the supply capacitor during the operation of the electronic control unit without the probe, which may result in incorrect sizing (under- or oversizing) of the supply capacitor on the basis of the disturbance of the additional elements added for the measurement.

In order to limit the generation of a parasitic inductance, a second known solution involves measuring the intensity of the current from the measurement of the voltage across the terminals of a resistive element placed in series with the capacitor. Such a measurement of the voltage is carried out using a measuring device, also called a “shunt”, connected to the terminals of the capacitor. However, as with the current probe, an additional wire, albeit of shorter length, is also necessary in order to connect the shunt across the terminals of the capacitor, which again generates a parasitic inductance. In addition, the shunt also generates a parasitic inductance due to its internal design, even if it is lower than that generated by the current probe. However, it is necessary to obtain a measurement that is as precise as possible in order to limit the error in the sizing of the supply capacitor, which could cause the supply capacitor to break prematurely and therefore represents a major drawback.

There is therefore still a need for a solution that makes it possible to overcome these drawbacks at least in part.

### SUMMARY OF THE INVENTION

The present invention aims to provide a simple, reliable, compact and efficient solution for measuring the intensity of the current flowing through the supply capacitor of an electronic control unit.

To this end, the subject of the present invention is a device for measuring the intensity of a current, suitable for measuring the intensity of a current flowing through a supply capacitor of an electronic control unit of a motor vehicle. Said device is notable in that it comprises at least one printed circuit, said printed circuit comprising at least one conductive layer and at least one first set of tracks printed on said at least one conductive layer, said first set of tracks comprising at least one first part having a first inductance and at least one second part having a second inductance, the first part and the second part being arranged so that the total inductance of the device is lower than each of the first inductance and the second inductance.

The device according to the invention makes it possible to determine as precisely as possible the intensity of the current flowing through the measuring device by virtue of the two parts of the first set of tracks, the shapes of which allow the total inductance generated by the measuring device to be limited. In particular, the total inductance generated by the measuring device is at least lower by half than the inductance generated by each of the first part and the second part Similarly, the total resistance generated by the measuring device is at least lower by half than the resistance generated by each of the first part and the second part It is thus possible to adjust the dimensions and the number of tracks to obtain a desired total resistance and/or total inductance value. The measuring device according to the invention can also advantageously be permanently installed in the vehicle in order to be used during the life of the vehicle.

More generally, when each part of the first set of tracks is called a “strand”, the total inductance generated by the measuring device is equal to the inductance generated by one strand divided by the number N of strands (N being an even number).

According to a first embodiment, when the first part and the second part of said at least one first set of tracks are mounted on the same conductive layer of the printed circuit, the shapes of the first part and the second part are symmetrical in order to limit the total inductance generated by the first set of tracks. This makes it possible to limit the size of the measuring device, while allowing its integration, on a single-layer printed circuit.

According to a second embodiment, when the printed circuit comprises at least two superposed conductive layers, and when each of the first part and the second part is mounted on one of the two conductive layers, the shape of the first part and the shape of the second part are identical and superposed in order to limit the total inductance generated by the first set of tracks. This makes it possible to optimize the size of the measuring device on a multilayer printed circuit. In addition, the integration of the measuring device on multiple layers allows a more flexible integration by limiting the size on the same layer.

Advantageously, the first part and the second part have symmetrical and/or identical shapes.

Advantageously, the first set of tracks comprises at least one track forming a succession of arms or zigzags in order to limit the inductance generated by a part of the first set of tracks.

Preferably, said at least one track comprises at least two arms, each defining two track portions extending parallel to one another.

According to a feature of the invention, the two track portions are connected by a perpendicular track portion.

More preferably, the distance between the two track portions is short in order to limit the inductance thus generated by said two arms.

According to one aspect of the invention, said two track portions are separated from one another by an insulating zone in order to electrically isolate the track portions.

Preferably, the track is in the form of a thickness of conductive material and said insulating zone is in the form of a slot formed along said track. This slot isolates the track from any other current flowing in the board, including the current flowing through other portions of the track and from the ground of the board. Such a slot can thus easily be manufactured during the printing of the first set of tracks on the printed circuit.

More preferably, the slot has a width of less than 0.2 mm, preferably less than 130 microns. Thus, the inductance generated by each branch has a low value, preferably lower than 3 nH.

The invention also relates to an electronic control unit of a plurality of injectors of a vehicle, said electronic control unit comprising at least one electronic board, said electronic board comprising a control module, a voltage converter, a supply capacitor and a drive module for the injectors, said control module being configured to control the drive module so that said drive module controls the injectors from a control current supplied by the converter via the supply capacitor. Said electronic board Is notable in that it comprises at least one measuring device as described above in order to determine the intensity of the current flowing through the supply capacitor.

Advantageously, when the supply capacitor has two terminals and the electronic board comprises a negative potential connector electrically connected to one of the terminals of the supply capacitor and a positive potential connector electrically connected to the other of the terminals of the supply capacitor, said measuring device is electrically connected to the supply capacitor at the negative potential connector in order to measure the intensity of the current flowing through the supply capacitor. The electronic control unit according to the invention also makes it possible to keep an equivalent ground (or floating ground), in other words without excess weight compared to a measuring device according to the prior art.

The invention further relates to a motor vehicle comprising a plurality of injectors and at least one electronic control unit as described above.

### BRIEF DESCRIPTION OF THE DRAWINGS

Other features and advantages of the invention will become apparent from the description that follows, which is provided with reference to the appended figures, which are provided by way of non-limiting example and in which identical reference signs are assigned to similar objects.

FIG. 1 schematically illustrates an electronic control unit according to the invention.

FIG. 2 schematically illustrates a first embodiment of the measuring device installed on the unit of FIG. 1.

FIG. 3 schematically shows a view along the section XX through the measuring device of FIG. 2.

FIG. 4 illustrates a partial view along the section AA of FIG. 2.

FIG. 5 schematically illustrates a second embodiment of the measuring device.

### DESCRIPTION OF THE PREFERRED EMBODIMENTS

The device according to the invention is intended to be installed in an electronic control unit of a combustion engine of a vehicle, in particular an automobile.

In a known manner, a combustion engine comprises fuel injectors and cylinders each defining a combustion chamber in which the combustion of a mixture of oxidant (air) and fuel injected by said injectors is triggered.

The device according to the invention makes it possible to measure the voltage defined across the terminals of a supply capacitor installed on an electronic board of the electronic control unit, such a voltage measurement making it possible to deduce therefrom the intensity of the current flowing through said supply capacitor as will be described later on.

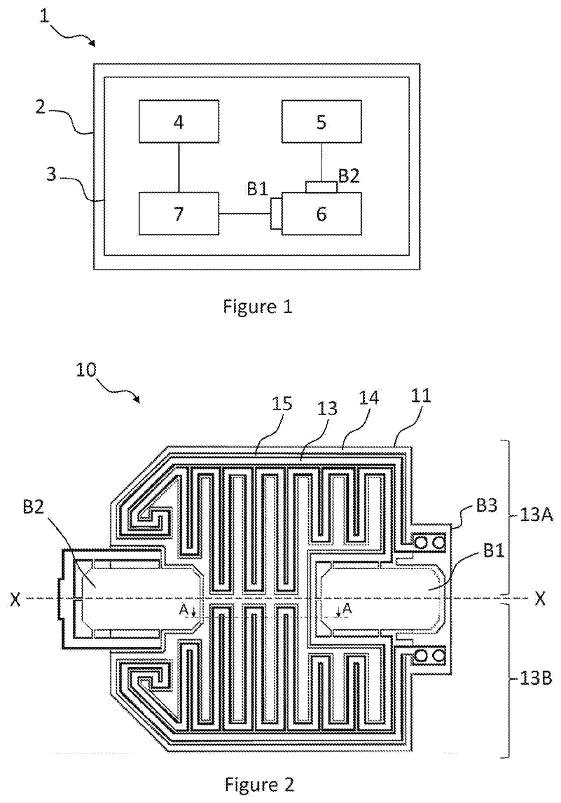

FIG. 1 has been used to schematically show an example of an electronic control unit according to the invention.

Electronic Control Unit 1

Such an electronic control unit 1, also called an ECU, makes it possible in particular to control the injection of fuel into the cylinders of the combustion engine of the vehicle. For this purpose, the electronic control unit 1 comprises a casing 2 in which is installed an electronic board 3 comprising multiple electronic circuits: a control module 4, a converter 5, a supply capacitor 6 and a drive module 7 for the fuel injectors. The electronic control unit 1 also has a ground potential, which is preferably the potential of its casing 2.

The control module 4 is adapted to generate control signals for the fuel injectors, in particular the instant and the duration of each fuel injection. These control signals are sent to the drive module 7. Such a control module 4 can in particular be in the form of a microcontroller. As the generation of such control signals is known, it will not be described in more detail.

The converter 5 is a direct-current-to-direct-current (DC-DC) converter suitable for converting a low voltage (for example provided by a 12 V supply battery of the vehicle) into a higher voltage required for controlling the opening of the injectors, for example of the order of 60 V. It will be noted that the converter 5 supplies, via the supply capacitor 6, this voltage to the drive module 7 so that the latter can control the opening of the injectors according to the control signals.

Supply Capacitor 6

The supply capacitor 6 comprises two connection terminals and is preferably of electrolytic type, more preferably of SMC, for surface mounted capacitor, also called SMD for surface mounted device, type.

The drive module 7 is able to control the various injectors from the control signals received from the control module 4 and to control the opening of the injectors using the high voltage received from the converter 5 via the supply capacitor 6.

In order to electrically connect the supply capacitor 6 to the electronic board 3, the electronic board 3 comprises a first electrical connector called “negative potential connector” B1 and a second electrical connector called “positive potential connector” B2, one terminal of the supply capacitor 6 being electrically connected to the negative potential connector B1 and the other terminal of the supply capacitor 6 being electrically connected to the positive potential connector B2.

In order to measure the voltage defined across the terminals of the supply capacitor 6, in particular to be able to size it (i.e. adapt its value to the operation of the electronic control unit 1), the electronic control unit 1 according to the invention comprises a measuring device.

Measuring Device

With reference to FIG. 2, the device is in the form of a printed circuit 10, also called a PCB (printed circuit board), connected to the negative potential connector B1 of the electronic board 3.

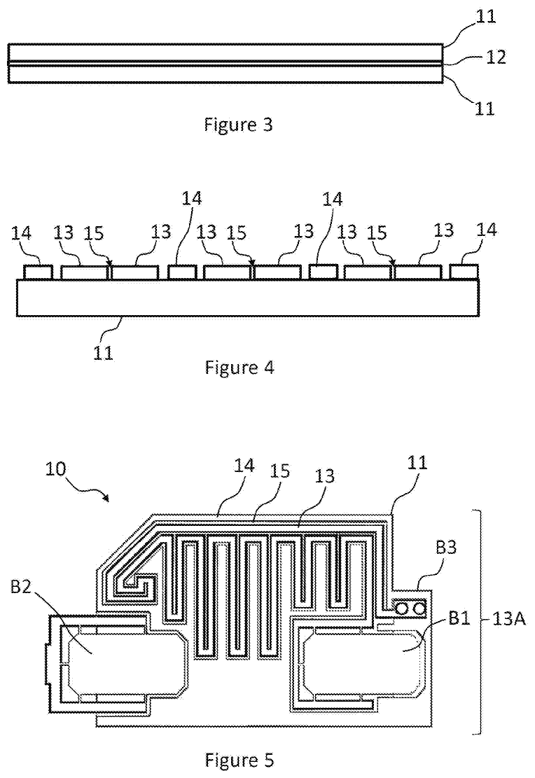

This printed circuit 10 can comprise one or more conductive layers 11 made of an electrically conductive material, for example copper. In the case of a printed circuit 10 comprising multiple conductive layers 11, the conductive layers 11 are separated from one another by insulating layers 12, as illustrated in FIG. 3, made of a material that is not electrically conductive. In other words, a multilayer printed circuit 10 has a succession of conductive layers 11 alternating with insulating layers 12. The conductive layers 11 and the insulating layers 12 are thus superposed one above the other.

According to the invention, the printed circuit 10 comprises at least one first set of tracks 13 and at least one second set of tracks 14, which are electrically conductive, etched on at least one conductive layer 11.

The first set of tracks 13 constitutes a shunt electrically connected to the negative potential connector B1 of the electronic board 3. This shunt is a connector device connected in series with the supply capacitor 6 for which it is desired to determine the value of the intensity of the current flowing through it. Such a shunt thus makes it possible to electrically connect the negative potential connector B1 to the ground potential B3 of the electronic control unit 1, as illustrated in FIG. 2. Certainly, in a series circuit, the intensity of the current has an identical value at any point in this circuit. The first set of tracks 13 thus makes it possible to perform a floating ground function for the terminal of the supply capacitor 6 connected to the negative potential connector B1.

The second set of tracks 14 makes it possible to electrically connect the first set of tracks 13 to the ground potential B3 of the electronic control unit 1.

An electric current flowing through the supply capacitor 6 between the negative potential connector B1 and the positive potential connector B2 also flows through the first set of tracks 13 and makes it possible to determine the intensity of the current flowing through the supply capacitor 6 as will be described later on.

In order to optimize the measurement of the intensity of the current, still referring to FIG. 2, the first set of tracks 13 comprises at least one first part 13A and one second part 13B.

The first part 13A has a first inductance L₁ and the second part 13B has a second inductance L₂. The inductance of each of the first part 13A and of the second part 13B is due to the magnetic field generated by the electric current flowing through the first part 13A and the second part 13B, respectively.

A first set of tracks 13 has been presented, constituting a shunt electrically connected to the negative potential connector B1 of the electronic board 3. However, it goes without saying that, in another embodiment, the first set of tracks 13 could be electrically connected to the positive potential connector B2 of the electronic board 3.

First Embodiment

In a first embodiment, the first part 13A and the second part 13B are printed so as to be symmetrical with respect to one another. In other words, the first part 13A and the second part 13B have perfectly symmetrical shapes along an axis of symmetry XX illustrated in FIG. 2. Due to their symmetrical shape, the first inductance L₁ of the first part 13A and the second inductance L₂ of the second part 13B have the same value. However, due to the symmetry of these shapes, the overall inductance L_{T} of the first set of tracks 13 is lower by half than the inductance of the inductances of the first part 13A and the second part 13B.

In other words:

$${L}_{T} = \frac{{L}_{1}}{2} = \frac{{L}_{2}}{2}$$

Thus, in this example, the measuring device makes it possible to halve the inductance generated by such a measuring device.

This makes it possible to limit the inductance of the measuring device and thus to make the measurement of the intensity of the current flowing through the supply capacitor 6 more reliable.

As illustrated in FIG. 2, the first set of tracks 13 is in the form of at least one track that is electrically conductive. In order to limit the size of the first set of tracks 13, the track comprises a plurality of arms forming sharp bends or zigzags.

In this example, each arm comprises two track portions extending parallel to one another and connected to one another at a first end of the arm by a perpendicular track portion. The arms are thus interconnected at their second end. In the example illustrated in FIG. 2, the track comprises seven arms, three arms of which are located between the negative potential connector B1 and the positive potential connector B2 of the electronic board 3. This makes it possible to make optimum use of the space available beneath the capacitor 6 while observing the electrical isolation distances between the tracks of the electrical circuit.

As illustrated in FIGS. 2 and 4, the various portions of the track are electrically isolated from one another by an insulating zone 15. As illustrated in FIG. 4, which represents FIG. 2 along the section AA, the first set of tracks 13 is in the form of a layer made of an electrically conductive material printed on a conductive layer 11. The insulating zone 15 is then in the form of a slot formed along the electrical track of each of the first part 13A and of the second part 13B of the first set of tracks 13. However, the slot does not extend to the point of contact between the track and either the negative potential connector B1 or the ground potential B3 in order to electrically connect them. Advantageously, the insulating zone 15 has a width of less than 0.2 mm, preferably of the order of 130 microns. This thus makes it possible to limit the distance between two parts of the zigzag track and therefore the inductance generated, which is proportional to this distance.

Still referring to FIG. 2, the second set of tracks 14 makes it possible to electrically connect the first set of tracks 13 to the ground potential B3 of the electronic control unit 1.

The second set of tracks 14 is also electrically isolated from the first set of tracks 13 by an insulating zone 15, which is in the form of a space or hollow, as shown in FIG. 4.

Second Embodiment

In a second embodiment of the measuring device according to the invention, illustrated in FIG. 5, the first part 13A and the second part 13B of the first set of tracks 13 are mounted on two different conductive layers 11 of the printed circuit 10.

In this example, the shapes of the first part 13A and of the second part 13B are identical and placed exactly to the right of one another. In other words, the shapes of the first part 13A and of the second part 13B are exactly superposed.

The first part 13A and the second part 13B are each included on a conductive layer 11 of the printed circuit 10, the conductive layers 11 being separated by an insulating layer 12, as illustrated in FIG. 3, adapted to electrically isolate the first part 13A and the second part 13B.

Such a superposition of identical patterns allows the inductances generated by each of the first part 13A and the second part 13B to interact in order to reduce by half the overall inductance of the first set of tracks 13 in comparison with the inductance of each of the first part 13A and the second part 13B.

Advantageously, the first set of tracks 13 could comprise more than one first part 13A and one second part 13B. Likewise, the first set of tracks 13 could combine parts symmetrical with one another and parts superposed on one another.

In particular, the first set of tracks 13 could comprise four parts (not shown) printed on two conductive layers 11. In this case, on each conductive layer 11, two parts symmetrical with one another are printed so as to halve the inductance on each conductive layer 11 in comparison with the inductance in a single part. The two parts of the same conductive layer 11 are identical and superposed on the two parts of the other conductive layer 11 so as to halve the inductance of the first set of tracks 13 in comparison with the inductance in a single conductive layer 11. In other words, a first set of tracks 13 comprising four parts makes it possible to quarter the inductance in comparison with the inductance in a single part.

The negative potential connector B1 and the positive potential connector B2 that connect the printed circuit 10 to the supply capacitor 6 are advantageously placed as close as possible to the terminals of the supply capacitor 6 in order to limit the inductance generated. Preferably, the printed circuit 10 is placed beneath the position of the supply capacitor 6. This makes it possible to use the space available beneath the supply capacitor 6 to print the first set of tracks 13 of the measuring device. Thus, if the measuring device is not kept during mass production, it will suffice not to print these tracks. And when sizing the supply capacitor 6, the first set of tracks 13 will not take up space on other printed tracks on the printed circuit 10 of the electronic control unit 1.

Measuring Method

The method for measuring the intensity of the current flowing through the supply capacitor 6 during the sizing of the latter will now be presented.

In a preliminary step, the resistance of the measuring device, in particular the resistance of the first set of tracks 13, is determined. For this purpose, a current I, the intensity value of which is known, is passed through the measuring device. The voltage U across the terminals of the measuring device, in other words between the negative potential connector B1 and the ground potential B3, is then measured. Then, the value of the intensity of the current I and the value of the voltage U measured are used to determine the value of the resistance R of the measuring device given by the formula:

$$U = R * I \\ or , \\ R = \frac{U}{I} \qquad ( 1 )$$

When the material used to form the printed circuit is copper, it is possible to define the resistance R of the measuring device as a function of the temperature (T) by extrapolating the measurement taken at room temperature (25° C.), using the formula

R(T)=R(25° C.)*[1+alpha(25)*(T−25)]

where alpha represents the temperature coefficient of the material over a given temperature range.

The value of the resistance R of the measuring device remains constant throughout the life of the measuring device and will be able to be reused for determining the intensity of the current flowing through the supply capacitor as will be described.

When using the measuring device, a current flows through the supply capacitor 6. However, when this current also flows through the measuring device between the negative potential connector B1 and the ground potential B3, the current has an intensity value identical to the value of the intensity of the current flowing through the supply capacitor 6 due to the series connection between the measuring device and the supply capacitor 6.

The value of the voltage across the terminals of the measuring device, i.e. between the negative potential connector B1 and the ground potential B3, is then measured in a known manner.

Then, the value determined beforehand for the resistance R of the measuring device and the value of the voltage U measured are used to determine the value of the intensity I of the current flowing through the measuring device that is given by formula (1).

This determined value of the intensity of the current corresponds to the value of the intensity of the current flowing through the supply capacitor 6, which then makes it possible to size the supply capacitor 6 so that it resists when using the electronic control unit 1. Certainly, when the measuring device has a reduced overall inductance, this inductance produces no or very little disturbance for the measurement of the intensity of the current.

Advantageously, the measuring device can be installed in the electronic control unit 1 just for the development phase of the motor vehicle. During mass production of this vehicle, the electronic control unit 1 then does not include a measuring device in order to limit the number of components and therefore the manufacturing costs of such an electronic control unit 1.

Alternatively, the electronic control unit 1 of a mass-produced vehicle could include the measuring device according to the invention. This makes it possible in particular to measure, throughout the life of the vehicle, the current flowing through the supply capacitor 6 in order to provide diagnoses for the latter. This can help detect a malfunction and thus prevent and anticipate a vehicle breakdown. A routine can be integrated in the control module for this purpose in order to collect and monitor the statistical consumption of the capacitor according to predefined modes of operation in the control module.

Advantageously, the measuring device generates a resistance due to the length and width of the tracks of the first set of tracks 13. Also, in the case of a supply capacitor 6 having zero or low internal resistance, in particular in the case of a supply capacitor of hybrid polymer type, the addition of the measuring device in series with a terminal of the supply capacitor 6 makes it possible to filter sudden oscillations in the current flowing through the supply capacitor 6 in order to prevent damage to the electrical circuit. The value of the resistance generated by the measuring device can then be chosen to be in a resistive value range allowing this protection.

1. A device for measuring the intensity of a current, suitable for measuring the intensity of a current flowing through a supply capacitor (6) of an electronic control unit (1) of a motor vehicle, said device comprising at least one printed circuit (10), said printed circuit (10) comprising at least one conductive layer (11) and at least one first set of tracks (13) printed on said at least one conductive layer (11), said first set of tracks (13) comprising at least one first part (13A) having a first inductance (L₁) and at least one second part (13B) having a second inductance (L₂), the first part (13A) and the second part (13B) being arranged so that the total inductance (L_{T}) of the device is lower than each of the first inductance (L₁) and the second inductance (L₂).

2. The device as claimed in claim 1, wherein when the first part (13A) and the second part (13B) of said at least one first set of tracks (13) are mounted on the same conductive layer (11) of the printed circuit (10), the shapes of the first part (13A) and the second part (13B) are symmetrical.

3. The device as claimed in claim 1, wherein the printed circuit (10) comprises at least two superposed conductive layers (11), and when each of the first part (13A) and the second part (13B) is mounted on one of the two conductive layers (11), the shape of the first part (13A) and the shape of the second part (13B) are identical and superposed.

4. The device as claimed in claim 1, wherein the first set of tracks (13) comprises at least one zigzag-shaped track having at least two arms, each defining two track portions extending parallel to one another.

5. The device as claimed in claim 4, wherein said two track portions are separated from one another by an insulating zone (15).

6. The device as claimed in claim 5, wherein when the track is in the form of a thickness of conductive material, said insulating zone is in the form of a slot formed along said track.

7. The device as claimed in claim 6, wherein said slot has a width of less than 0.2 mm.

8. An electronic control unit (1) of a plurality of injectors of a vehicle, said electronic control unit (1) comprising at least one electronic board (3), said electronic board (3) comprising a control module (4), a voltage converter (5), a supply capacitor (6) and a drive module (7) for the injectors, said control module (4) being configured to control the drive module (7) so that said drive module (7) controls the injectors from a control current supplied by the converter (5) via the supply capacitor (6), said electronic board (3) comprising at least one measuring device as claimed in claim 1 in order to determine the intensity of the current flowing through the supply capacitor (6).

9. The electronic control unit (1) as claimed in claim 8, wherein when the supply capacitor (6) has two terminals and the electronic board (3) comprises a negative potential connector (B1) electrically connected to one of the terminals of the supply capacitor (6) and a positive potential connector (B2) electrically connected to the other of the terminals of the supply capacitor (6), said measuring device is electrically connected to the supply capacitor (6) at the negative potential connector (B1) in order to measure the intensity of the current flowing through the supply capacitor (6).

10. A motor vehicle comprising a plurality of injectors and at least one electronic control unit (1) as claimed in claim 9.

11. The device as claimed in claim 2, wherein the first set of tracks (13) comprises at least one zigzag-shaped track having at least two arms, each defining two track portions extending parallel to one another.

12. The device as claimed in claim 3, wherein the first set of tracks (13) comprises at least one zigzag-shaped track having at least two arms, each defining two track portions extending parallel to one another.

13. The device as claimed in claim 6, wherein said slot has a width of less than 130 microns.

14. An electronic control unit (1) of a plurality of injectors of a vehicle, said electronic control unit (1) comprising at least one electronic board (3), said electronic board (3) comprising a control module (4), a voltage converter (5), a supply capacitor (6) and a drive module (7) for the injectors, said control module (4) being configured to control the drive module (7) so that said drive module (7) controls the injectors from a control current supplied by the converter (5) via the supply capacitor (6), said electronic board (3) comprising at least one measuring device as claimed in claim 2 in order to determine the intensity of the current flowing through the supply capacitor (6).

15. An electronic control unit (1) of a plurality of injectors of a vehicle, said electronic control unit (1) comprising at least one electronic board (3), said electronic board (3) comprising a control module (4), a voltage converter (5), a supply capacitor (6) and a drive module (7) for the injectors, said control module (4) being configured to control the drive module (7) so that said drive module (7) controls the injectors from a control current supplied by the converter (5) via the supply capacitor (6), said electronic board (3) comprising at least one measuring device as claimed in claim 3 in order to determine the intensity of the current flowing through the supply capacitor (6).

16. An electronic control unit (1) of a plurality of injectors of a vehicle, said electronic control unit (1) comprising at least one electronic board (3), said electronic board (3) comprising a control module (4), a voltage converter (5), a supply capacitor (6) and a drive module (7) for the injectors, said control module (4) being configured to control the drive module (7) so that said drive module (7) controls the injectors from a control current supplied by the converter (5) via the supply capacitor (6), said electronic board (3) comprising at least one measuring device as claimed in claim 4 in order to determine the intensity of the current flowing through the supply capacitor (6).

17. An electronic control unit (1) of a plurality of injectors of a vehicle, said electronic control unit (1) comprising at least one electronic board (3), said electronic board (3) comprising a control module (4), a voltage converter (5), a supply capacitor (6) and a drive module (7) for the injectors, said control module (4) being configured to control the drive module (7) so that said drive module (7) controls the injectors from a control current supplied by the converter (5) via the supply capacitor (6), said electronic board (3) comprising at least one measuring device as claimed in claim 5 in order to determine the intensity of the current flowing through the supply capacitor (6).

18. An electronic control unit (1) of a plurality of injectors of a vehicle, said electronic control unit (1) comprising at least one electronic board (3), said electronic board (3) comprising a control module (4), a voltage converter (5), a supply capacitor (6) and a drive module (7) for the injectors, said control module (4) being configured to control the drive module (7) so that said drive module (7) controls the injectors from a control current supplied by the converter (5) via the supply capacitor (6), said electronic board (3) comprising at least one measuring device as claimed in claim 6 in order to determine the intensity of the current flowing through the supply capacitor (6).

19. An electronic control unit (1) of a plurality of injectors of a vehicle, said electronic control unit (1) comprising at least one electronic board (3), said electronic board (3) comprising a control module (4), a voltage converter (5), a supply capacitor (6) and a drive module (7) for the injectors, said control module (4) being configured to control the drive module (7) so that said drive module (7) controls the injectors from a control current supplied by the converter (5) via the supply capacitor (6), said electronic board (3) comprising at least one measuring device as claimed in claim 7 in order to determine the intensity of the current flowing through the supply capacitor (6).

20. An electronic control unit (1) of a plurality of injectors of a vehicle, said electronic control unit (1) comprising at least one electronic board (3), said electronic board (3) comprising a control module (4), a voltage converter (5), a supply capacitor (6) and a drive module (7) for the injectors, said control module (4) being configured to control the drive module (7) so that said drive module (7) controls the injectors from a control current supplied by the converter (5) via the supply capacitor (6), said electronic board (3) comprising at least one measuring device as claimed in claim 12 in order to determine the intensity of the current flowing through the supply capacitor (6).
